(19) United States
(12) Patent Application Publication
(10) Pub. No.: US 2007/0101219 A1
(43) Pub. Date: May 3, 2007

(54) Semiconductor testing apparatus and method of calibrating the same

(76) Inventors: Seung-Ho Jang, Cheonan-si (KR); Chul-Woong Jang, Cheonan-si (KR); Min-Seok Jang, Seongnam-si (KR); Se-Kyung Oh, Seongnam-si (KR); Hyun-Seop Shim, Bupyeong-gu (KR); Jae-Il Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/580,048

(22) Filed: Oct. 13, 2006

(30) Foreign Application Priority Data
Oct. 14, 2005 (KR) 2005-97021

(51) Int. Cl. G01R 31/28

(52) U.S. Cl. 714/724

(57) ABSTRACT

A calibration method and a semiconductor testing apparatus, including N drivers, N being a natural number no less than two, at least one transmission path coupled to at least one of the N drivers, at least one calibration board coupled to the at least one transmission path, N comparators, and N delay paths, such that each delay path of the N delay paths has a skew value and is coupled between the calibration board and one of the N comparators.

### BACKGROUND OF THE INVENTION

1. Field of the Invention

The present invention relates to a semiconductor testing apparatus and a method of calibrating the same. In particular, the present invention relates to a novel semiconductor testing apparatus exhibiting reduced calibration timing of input/output signals during testing of semiconductors.

2. Description of the Related Art

In general, semiconductors may be tested after the manufacturing process is complete to ensure proper operation and lack of defects. Such testing may include application of test signals to a semiconductor device, i.e., device under test (DUT), measurement of the DUT response, and comparison between the measured response and the designed response. In particular, such testing devices may include pin electronics PE having a plurality of drivers and a plurality of comparators. The drivers may provide test clock signals, i.e., input signals, to the DUT through input/output (I/O) pins of an IC socket mounted on a socket board, and the comparators may receive and analyze output signals from the DUT in response to the test clock signals of the drivers. Any deviation between the measured and designed DUT output signals may be adjusted and remedied.

However, when an input signal is generated and transmitted into the DUT, a time deviation, i.e., a time skew, may be generated as a result of the length of the transmission line(s) between the driver and the DUT and/or the number of the outer DUT terminals that receive input signals. Additionally, the time deviation may result due to environmental factors, e.g., temperature and humidity. Subsequently, the timing of the DUT output signals and their analysis may be extended, thereby causing inaccurate overall timing and test results. Accordingly, it may be desirable to adjust the timing of the DUT input/output signals with a calibration process in order to account for accurate signal deviation and/or degradation prior to the DUT testing.

Conventional calibration components in semiconductor testing apparatuses may include either relay systems coupled to multiplexers that may degrade the signal quality and accuracy, as well as, slow down the overall calibration process, or a large number of drivers and comparators operated individually, i.e., a driver and a comparator on a pin electronics card for each respective I/O terminal, that may require complex construction, lengthy procedure, and complicated operation to complete the calibration procedure.

Therefore, there remains a need for a semiconductor testing apparatus and a method of calibrating the same, capable of providing accurate calibration procedure thereof in a relatively short time.

### SUMMARY OF THE INVENTION

The present invention is therefore directed to a semiconductor testing apparatus and a method of calibrating the same, which substantially overcome one or more of the problems due to the limitations and disadvantages of the related art.

It is therefore a feature of an embodiment of the present invention to provide a semiconductor testing apparatus having a large number of drivers/comparators corresponding to a plurality of semiconductor terminals and capable of providing accurate calibration thereof in a relatively short time.

It is another feature of an embodiment of the present invention to provide a method of calibrating a semiconductor testing apparatus exhibiting reduced calibration timing of input/output signals during testing of semiconductors.

At least one of the above and other features of the present invention may be realized by providing a semiconductor testing apparatus, having N drivers, N being a natural number no less than two, at least one transmission path coupled to at least one of the N drivers, at least one calibration board coupled to the at least one transmission path, N comparators, and N delay paths, wherein each delay path of the N delay paths has a skew value and is coupled between the calibration board and one of the N comparators. The skew value of each of the N delay paths may be unique.

The at least one calibration board may include N fan-out buffers, wherein each fan-out buffer of the N fan-out buffers may have a first calibration predetermined delay value. The calibration board may also have a number and configuration of channels that is comparable to a number and configuration of terminals of a device under test.

The at least one transmission path may have a first transmission predetermined delay value. The semiconductor testing apparatus may further include N transmission paths, wherein each transmission path of the N transmission paths may have a skew value.

Additionally, the semiconductor testing apparatus of the present invention may include a second calibration board with N transmission channels, wherein each transmission channel of the N transmission channels may have a second calibration predetermined delay value. Each transmission channel of the N transmission channels may include a printed circuit board. Additionally, each transmission channel of the N transmission channels may include a fan-out buffer. The first calibration predetermined delay value may be equal to the second calibration predetermined delay value.

In another aspect of the present invention, there is provided a method of calibrating a semiconductor testing apparatus having N drivers and N comparators, N being a natural number no less than two, the method including generating N first test clock signals by the N drivers, transmitting the N first test clock signals to a first calibration board to generate N first response clock signals, passing each response clock signal of the N first response clock signals through one of N delay paths into one of the N comparators to generate N first output signals, comparing each output signal of the N first output signals to a reference value to obtain a first skew value for each delay path of the N delay paths, generating N second test clock signals by the N drivers, transmitting the N second test clock signals to a second calibration board to generate N second response clock signals, passing each response clock signal of the N second response clock signals through one of N delay paths into one of the N comparators to generate N second output signals, and subtracting from each output signal of the N second output signals the first skew value of a corresponding output signal of the N first output signals to determine N second skew values.

Comparing each output signal of the N first output signals to a reference value may include measuring phase differences between a first output signal of the N first output signals and each of the N first output signals. Comparing each output signal of the N first output signals to a reference value may further include adjusting the N first skew values to have desirable values.

Transmitting the N second test clock signals to a second calibration board may include passing the N second test clock signals through N transmission paths having transmission delay values.

Determining the N second skew values may include calculating corresponding transmission delay values. Calculating the transmission delay values may include adjusting the transmission delay values to have desirable values.

The method may further include calibrating each output signal of the N second output signals to have desirable values.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a conceptual view of a semiconductor testing apparatus according to an embodiment of the present invention;

FIG. 2 illustrates a block diagram of a semiconductor testing apparatus according to an embodiment of the present invention;

FIG. 3 illustrates a block diagram of a semiconductor testing apparatus according to another embodiment of the present invention;

FIG. 4 illustrates a timing diagram of clock signals outputted from respective comparators of the semiconductor testing apparatus illustrated in FIG. 2;

FIG. 5 illustrates a timing diagram of clock signals outputted from respective comparators of the semiconductor testing apparatus illustrated in FIG. 3;

FIG. 6 illustrates a block diagram of time delays in the semiconductor testing apparatus illustrated in FIG. 2;

FIG. 7 illustrates a block diagram of time delays in the semiconductor testing apparatus illustrated in FIG. 3; and

FIG. 8 illustrates a block diagram of a semiconductor testing apparatus according to another embodiment of the present invention.

### DETAILED DESCRIPTION OF THE INVENTION

Korean Patent Application No. 2005-97021, filed on Oct. 14, 2005, in the Korean Intellectual Property Office, and entitled: “Method of Calibrating Semiconductor Testing Apparatus, and Semiconductor Testing Apparatus,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers, elements, and regions may be exaggerated for clarity of illustration.

It will also be understood that when an element is referred to as being “on” another element or substrate, it can be directly on the other element or substrate, or intervening elements may also be present. Further, it will be understood that when an element is referred to as being “under” another element, it can be directly under, or one or more intervening elements may also be present. In addition, it will also be understood that when an element is referred to as being “between” two elements, it can be the only element between the two elements, or one or more intervening elements may also be present. Likewise, it will be understood that when an element or layer is referred to as being “connected to” or “coupled to” another element or layer, it can be directly connected to or coupled to the other element or layer or intervening elements or layers may be present. In contrast, when an element is referred to as being “directly on,” “directly connected to,” or “directly coupled to” another element or layer, there may be no intervening elements or layers present. Like reference numerals refer to like elements throughout.

As used herein, the term “and/or” may include any and all combinations of one or more of the associated listed items.

As further used herein, the singular forms “a,” “an” and “the” are intended to include the plural forms as well, unless the context clearly indicates otherwise.

Unless otherwise defined, all terminology used herein is given its ordinary meaning in the art, and therefore, should be interpreted within the context of the specification and the relevant art as understood by one of ordinary skill.

It should further be noted with respect to the present invention that “time skew” or like terminology refers hereinafter to signal time deviation as related to time phase shift from a logic-low state to a logic-high state at different times. The term “skew value” or like terminology hereinafter refers to specific times delays in picoseconds (ps) produced by specific components as measured during apparatus calibration. Finally, the term “predetermined delay value” or like terminology refers to stored and/or predetermined delay values associated with specific components.

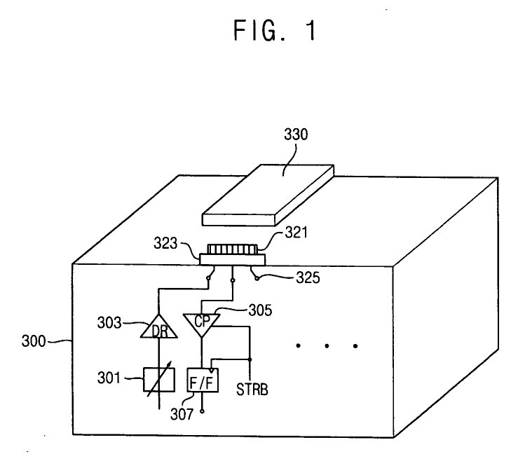

A conceptual embodiment of a semiconductor testing apparatus of the present invention will now be described in detail with reference to FIG. 1. As illustrated in FIG. 1, the semiconductor testing apparatus may include a semiconductor testing unit 300 and a calibration block 330.

The semiconductor testing unit 300 may include a plurality of variable delay circuits 301, a plurality of drivers 303, a plurality of comparators 305, and a plurality of flip-flops 307 for performing timing calibration procedures.

Each driver 303 of the semiconductor testing unit 300 may be connected to a corresponding individual I/O pin 325, such that each driver 303 may generate a test clock signal and transmit it through its corresponding I/O pin 325 to the calibration block 330.

Each comparator 305 of the semiconductor testing unit 300 may be connected to a corresponding individual I/O pin 325, such that each comparator 305 may receive a response clock signal from the calibration block 330 through its corresponding I/O pin 325. Further, each comparator 305 may compare the response clock signal received from the calibration block 330 to a strobe signal STRB, i.e., a reference signal determined in advance with respect to the DUT voltage, to generate an output signal. For example, if the response clock signal is higher than the reference signal, i.e., if the response clock signal received is late relatively to the reference signal, then the comparator 305 may generate an output signal indicating a logic-high (“1”) state. Alternatively, if the response clock signal is lower than the reference signal, i.e., if the response clock signal received is early relatively to the reference signal, the comparator 305 may generate an output signal indicating a logic-low (“0”) state.

Each flip-flop 307 may have at least one input and at least one output. In particular, each flip-flop 307 may be in communication with a respective comparator 305, such that each flip-flop 307 may receive the output signal from its respective comparator 305. Each flip-flop 307 may also be in communication with the strobe signal STRB, such that each flip-flop 307 may receive a signal indicating rising or falling timing edge. Accordingly, each flip-flop 307 may output a signal based on the output and strobe signals.

The calibration block 330 according to an embodiment of the present invention may provide a medium for holding a DUT (not shown) during testing and calibration. In particular, the calibration block 330 may be connected to the semiconductor testing unit 300 through a socket board interface having a socket board 323, an integrated circuit (IC) socket 321, and a plurality of I/O pins 325. Each I/O pin 325 may be in communication with a channel, i.e., test signal path of a DUT terminal, of the semiconductor testing apparatus of the present invention, such that the plurality of the I/O pins 325 may be in communication with the semiconductor testing unit 300 to transmit test clock signals from the semiconductor testing unit 300 to the calibration block 330 through the socket board 323 and the IC socket 321 and vice versa. Accordingly, test clock signals may be transmitted from the semiconductor testing unit 300 through the calibration block 330 to the DUT for testing and/or calibration purposes.

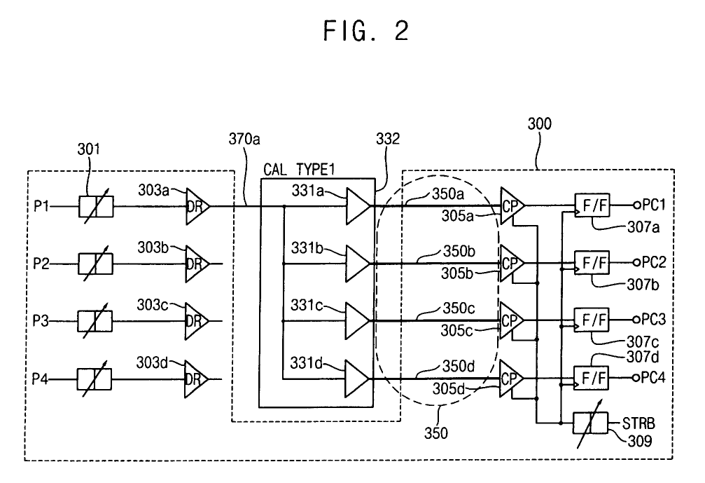

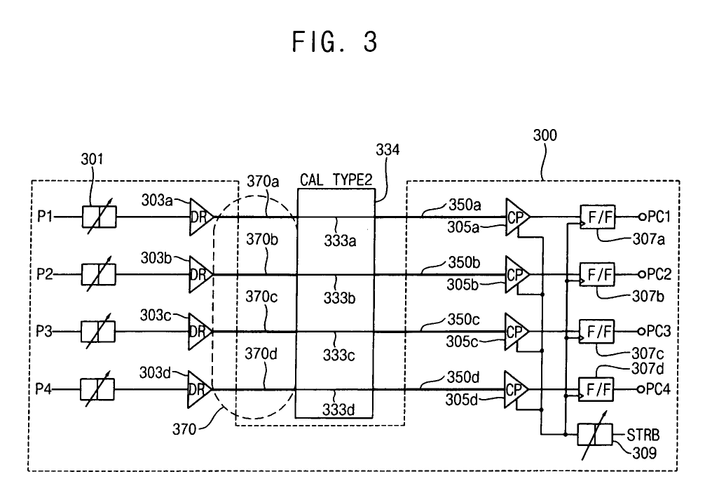

The calibration block 330 may include at least a first calibration board 332, as illustrated in FIG. 2. Preferably, the calibration block 330 may include the first calibration board 332 and a second calibration board 334, as illustrated in FIGS. 2-3. Each calibration board, e.g., first calibration board 332 or second calibration board 334, may be disassembled from the calibration block 330 and replaced with a different calibration board with respect to the DUT configuration and the required calibration and/or testing procedures.

The first and second calibration boards 332 and 334, respectively, may have a number and configuration of terminals corresponding to the number and configuration of the inlet/outlet channels of the DUT. In other words, the terminals of the calibration boards, e.g., the first and second calibration boards 332 and 334, may have the same number and may be arranged in the same geometric or planar configuration as the inlet/outlet channels of the DUT to provide communication therebetween.

Exemplary embodiments of operation of components of the semiconductor testing unit 300, the calibration block 330 and the calibration of their respective signals will be described hereinafter with respect to FIGS. 2-5, which illustrate four channels of the plurality of channels included in the semiconductor testing apparatus of the present invention.

It should be noted with respect to the following embodiments that a plurality of components will be collectively referred to hereinafter with a single reference numeral, and each individual component of the plurality of components will be indicated hereinafter with the collective reference numeral and an additional reference character. For example, each individual driver of the plurality of drivers 303 will be referred to hereinafter as 303a, 303b, 303c, and so forth. Similar terminology will be applied to each individual component of the plurality of comparators 305, the plurality of flip-flops 307, and the plurality of other components to be described below.

As illustrated in FIG. 2, the calibration block 330 may include a first calibration board 332 having a plurality of fan-out buffers 331, i.e., fan-out buffers 331a, 331b, 331c and 331d, having a predetermined delay value.

The number of fan-out buffers 331 may correspond to the number of channels, i.e., the number of the I/O pins 325. The plurality of fan-out buffers 331 may be connected to the drivers 303 of the semiconductor testing unit 300 at one side, i.e., a test clock signal may be transmitted from any driver 303 into any of the fan-out buffers 331, and to the comparators 305 of the semiconductor testing unit 300 at the other side, i.e., a response clock signal may be transmitted from a specific fan-out buffer 331 to a corresponding comparator 305. In this respect it should be noted that according to an embodiment of the present invention, each fan-out buffer 331, i.e., fan-out buffer 331a, 331b, and so forth, may have the same predetermined delay value, i.e., first calibration predetermined delay value.

As further illustrated in FIG. 2, the semiconductor testing unit 300 may include a plurality of delay circuits 301, a plurality of drivers 303, a plurality of delay paths 350, a plurality of comparators 305, and a plurality of flip-flops 307. In particular, each driver of the plurality of drivers 303, i.e., first driver 303a, second driver 303b, and so forth, may be connected to the plurality of fan-out buffers 331 via a first transmission path 370a, such that a test clock signal may be transmitted from a specific driver 303 through the first transmission path 370a into one of the fan-out buffers 331 of the first calibration board 332. In this respect, it should be noted that the first transmission path 370a may have a first transmission predetermined delay value.

Further, the test clock signal transmitted into a specific fan-out buffer 331 may be passed from the first calibration board 332 back into the semiconductor testing unit 300 through a specific delay path 350 having a specific skew value. In other words, each fan out buffer 331 may be connected through a specific delay path 350 to a specific comparator 305 and, subsequently, to a specific flip-flop 307 for calibration purposes.

The first transmission predetermined delay value of the first transmission path 370a and the first calibration predetermined delay value of each fan-out buffer 331 may be identical. However, the skew values of the delay paths 350 may not be identical, i.e., each delay path 350a, and so froth, may have a unique skew value. In this regard, a “unique skew value” indicates that each specific delay path 350 may have a certain skew value that is distinguishable over the skew values of the other delay paths 350.

Accordingly, a test clock signal generated in any driver 303, e.g., first driver 303a, may have the same time skew at the exit from any fan-out buffer 331, regardless of the specific fan-out buffer 331 employed. However, the time skew of the same clock signal may vary at the exit from each comparator 305 due to the specific delay path 350, e.g., first delay path 350a, second delay path 350b, and so forth, employed. Therefore, each output signal from a specific comparator 305 into a specific flip-flop 307 may exhibit a different time skew, i.e., different time phases due to a shift from a logic-low state to a logic-high state at different times. In this respect, it should be noted that the strobe signal STRB may be adjusted via a variable delay circuit 309 to vary a timing of the shift from a logic-low state to a logic-high state.

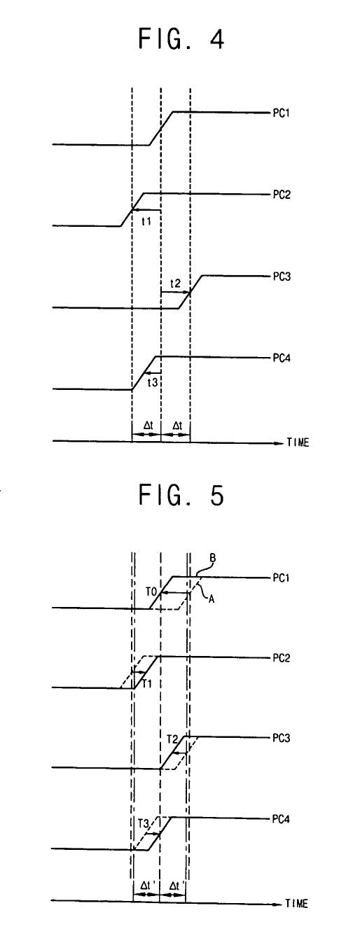

The clock signals outputted from each comparator 305 into a specific flip-flop 307, i.e., PC1 through PC4, are illustrated in more detail with respect to FIG. 4.

The respective clock signals outputted from the second, third and fourth flip-flops 307b, 307c and 307d, with respect to the clock signal outputted from the first flip-flop 307a, may have skew values of t1, t2, and t3, respectively, as illustrated in FIG. 4. For example, the PC2 signal outputted from the comparator 305b into the flip-flop 307b, after passing through the second delay path 350b, may have a skew value of t1, as compared to a clock signal passing through the first delay path 350a of the comparator 305a into the flip-flop 307a, i.e. PC1 signal.

Each specific delay path 350 of a specific comparator 305 may be adjusted in advance, such that its corresponding skew value may have a desirable value. Once the skew value of each specific delay path 350 of a specific comparator 305 is adjusted to the desirable value, it may be stored for calibrating the semiconductor testing apparatus of the present invention. In this respect, it should be noted that a “desirable value” refers to a delay value employed for calibrating the clock signal, e.g., less than about 100 ps.

As illustrated in FIG. 3, the calibration block 330 may include a second calibration board 334 having a plurality of transmission channels 333, e.g., first transmission channel 333a, second transmission channel 333b, and so forth. The transmission channels 333 may have a predetermined delay value, such that each specific transmission channel 333, i.e., transmission channel 333a, 333b, and so forth, may have the same predetermined delay value, i.e., second calibration predetermined delay value. Each specific transmission channel 333 may be connected to a specific driver 303 of the semiconductor testing unit 300 at one side, e.g., a test clock signal may be transmitted from the first driver 303a into a transmission channel 333a of the second calibration board 334, and to a specific comparator 305 of the semiconductor testing unit 300 at the other side, e.g., a response clock signal may be transmitted from the transmission channel 333a into the first comparator 305a.

As further illustrated in FIG. 3, the semiconductor testing unit 300 may include a plurality of transmission paths 370. Accordingly, each driver of the plurality of drivers 303, i.e., first driver 303a, second driver 303b, and so forth, of the semiconductor testing unit 300 may be connected to a specific transmission channel 333 via a specific transmission path 370, such that a test clock signal may be transmitted from a specific driver 303, e.g., first driver 303a, through a specific transmission path 370, e.g., first transmission path 370a, into a specific transmission channel 333, e.g., first transmission channel 333a, of the second calibration board 334. In this respect it should be noted that each of the plurality of the transmission paths 370 may have a different skew value, i.e., each transmission paths 370a, 370b, and so forth, may have a unique skew value. In this regard, a “unique skew value” indicates that each specific transmission path 370 may have a certain skew value that is distinguishable over the skew values of the other transmission paths 370.

Further, the test clock signal transmitted into a specific transmission channel 333 may be passed from the second calibration board 334 back into the semiconductor testing unit 300 through a specific delay path 350. In other words, each transmission channel 333 may be connected through a specific delay path 350 to a specific comparator 305 and, subsequently, to a specific flip-flop 307 for calibration purposes. In this respect, it should be noted that the skew values of each delay path 350 may not be identical, i.e., each delay path 350a, 350b, and so forth, may have a unique skew value.

Accordingly, a clock signal generated by a specific driver 303, e.g., first driver 303a, may have a specific time skew at the exit of a specific delay path 350, e.g., first delay path 350, as dependent on the specific transmission path 370, e.g., first transmission path 370a, and the specific delay path 350, e.g., first delay path 350a, employed. Therefore, each output signal from a specific comparator 305 into a specific flip-flop 307, i.e., PC1 through PC4, may exhibit a different time skew. In this respect, it should be noted that the strobe signal STRB may be adjusted via a variable delay circuit 309 to vary a timing of the shift from a logic-low state to a logic-high state.

The clock signals outputted from each comparator 305 into a specific flip-flop 307, i.e., PC1 through PC4, in FIG. 3 are illustrated as dotted lines “A” in FIG. 5.

As illustrated in FIG. 5, the respective signals PC1 through PC4 outputted from the first, second, third and fourth flip-flops 307a, 307b, 307c and 307d, respectively, may reflect the respective time skews of the initial test clock signals transmitted from the drivers 303 due to time delay accumulated in the transmission paths 370, transmission channels 333, and delay paths 350.

As previously discussed with respect to FIGS. 2 and 4, the skew values of each specific delay path 350 of a specific comparator 305 may be adjusted to a desired value with a first calibration board 332 and stored as predetermined skew values. Having the predetermined skew values of each specific delay path 350 may facilitate evaluating and setting skew values of each transmission path 370. In particular, the predetermined skew value, i.e., the stored skew value, which is based on measurement and calculation with respect to the first calibration board 332, of each specific delay path 350 may be subtracted from each respective skew value “A”, i.e., a measured skew value with respect to the second calibration board 334, to evaluate each specific transmission path 370. For example, the predetermined skew value of delay path 350a, determined and stored as discussed with respect to FIG. 4, may be subtracted from the PC1 signal in FIG. 5 in order to calculate the skew value of the first transmission path 370a. Each skew value of a specific transmission path 370 may be adjusted to have a desirable value, and it may be stored as a predetermined transmission skew value.

As further illustrated in FIG. 5, the time skew of clock signal “A” may be calibrated to have a different time skew, i.e., clock signal “B” illustrated with a solid line. For example, the PC1 signal “A” may be adjusted by a time TO to have a time skew “B.” Similarly, as illustrated in FIG. 5, signals PC2 through PC4 may be adjusted by times T1, T2 and T3, respectively, by controlling a plurality of variable delay circuits 301, each specific delay circuit 301 corresponding to a respective channel.

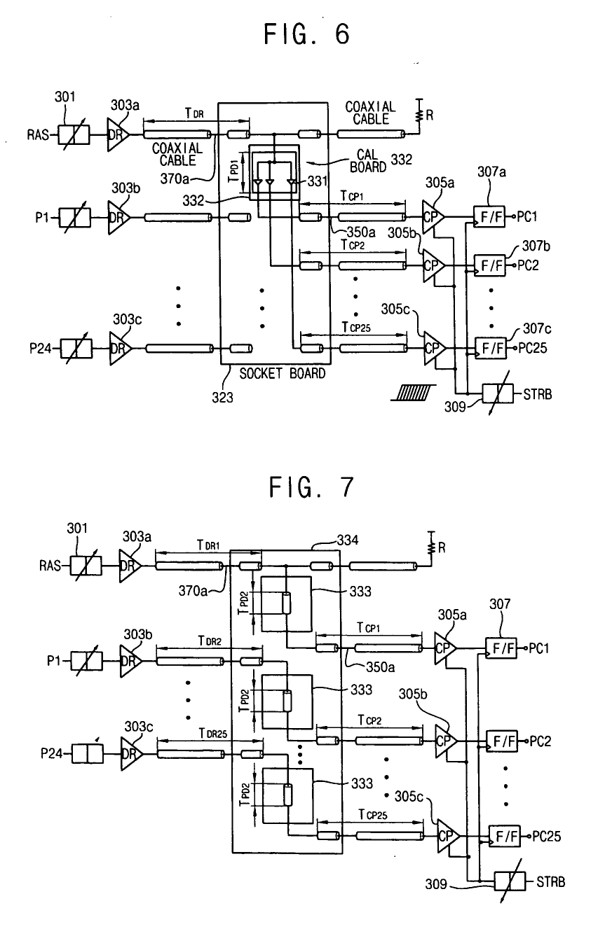

The time delays generated by the different components of the testing apparatus of the present invention are discussed in further detail with respect to FIGS. 6-7 that illustrate exemplary embodiments of semiconductor testing apparatuses having 25 testing channels. It should be noted that specific details of components and elements of the testing apparatus illustrated in FIGS. 6-7 that have been previously discussed with respect to FIGS. 1 to 5 will not be repeated hereinafter.

As illustrated in FIG. 6, an exemplary first driver 303a of the plurality of drivers 303 may be connected to a plurality of fan-out buffers 331 in the first calibration board 332 through a first transmission path 370a having a first transmission predetermined delay value of TDR. Further, the plurality of fan-out buffers 331 having a first calibration predetermined delay value of TPD1 may be connected to the plurality of comparators 305 via the plurality of delay paths 350 having skew values of TCP1, TCP2 . . . , TCP25, respectively, i.e., each fan-out buffer 331 having a first calibration predetermined delay value of TPD1 may be connected to a specific comparator 305, e.g., first comparator 305a, second comparator 305b, and so forth, via a respective delay path 350, e.g., first delay path 350a, second delay path 350b, and so forth, having a respective skew value, e.g., TCP1, TCP2, . . . , TCP25.

The first transmission predetermined delay value TDR and the first calibration predetermined delay value TPD1 may be measured, adjusted, and stored in advance as previously discussed with respect to FIGS. 2 and 4. The skew values of the delay paths 350 TCP1, TCP2, . . . , TCP25 may be obtained by subtracting the first transmission predetermined delay value TDR and the first calibration predetermined delay value TPD1 from a final measured signal including the measured skew values of TDR, TPD1 and respective TCP, e.g., one of TCP1, TCP2, . . . , TCP25, as previously discussed with respect to FIGS. 2 and 4, as well.

In particular, a time skew of a clock signal outputted from the first flip-flop 307a may be obtained by evaluating the skew value t1 between a clock signal outputted from a second flip-flop 307b and the first flip-flop 307a. For example, if the clock signal outputted from the second flip-flop 307b has a minimum value, a t1 value may be calculated by subtracting the clock signal outputted from the second flip-flop 307b from the clock signal outputted from the first flip-flop 307a. Accordingly, the time skews obtained for each of the plurality of flip-flops 307, e.g., 307a, 307b, and so forth, due to the third delay paths TCP1, TCP2, . . . , TCP25 of the respective comparators 305 may be determined and stored in advance as predetermined skew values.

As illustrated in FIG. 7, the plurality of drivers 303 may be connected to a plurality of transmission channels 333 in the second calibration board 334 through a plurality of transmission paths 370. Each specific transmission path 370 may have a transmission predetermined delay value, e.g., first transmission predetermined delay value TDR1, second transmission predetermined delay value TDR2, . . . , twenty fifth transmission predetermined delay value TDR25. Further, each specific transmission channel 333 may have a second calibration predetermined delay value of TPD2, and each specific transmission channel 333 may be connected to a respective comparator 305 via a specific delay path 350 having a specific skew value of TCP1, TCP2, . . . , TCP25, respectively. In this case, the specific skew values TCP1, TCP2, . . . , TCP25 are predetermined skew values previously discussed with respect to FIG. 6.

For example, a test clock signal outputted from an exemplary driver 303a may be transmitted through a first transmission path 370a having a first transmission predetermined delay value of TDR1 into a transmission channel 333 having a second calibration predetermined delay value of TPD2. Further, the signal may be passed through a delay path 350a having a skew value of TCP1 into comparator 305a and flip-flop 307a to output a signal PC1. Once all relevant skew values are set to desirable values, outputted signals that are skewed may be calibrated according to the procedure previously discussed with respect to signals “A” and “B” in FIG. 5.

The second calibration predetermined delay value TPD2 may be measured, adjusted, and stored in advance as previously discussed with respect to FIGS. 3 and 5. The transmission predetermined delay values TDR1, TDR2, . . . , TDR25 may be obtained by subtracting the second calibration predetermined delay value TPD2 and the predetermined skew values of the delay paths 350 TCP1, TCP2, . . . , TCP25, calculated in FIG. 6, from a final measured signal including the measured skew values of TDR, TPD2 and respective TCP, e.g., one of TCP1, TCP2, . . . , TCP25, as previously discussed with respect to FIGS. 3 and 5.

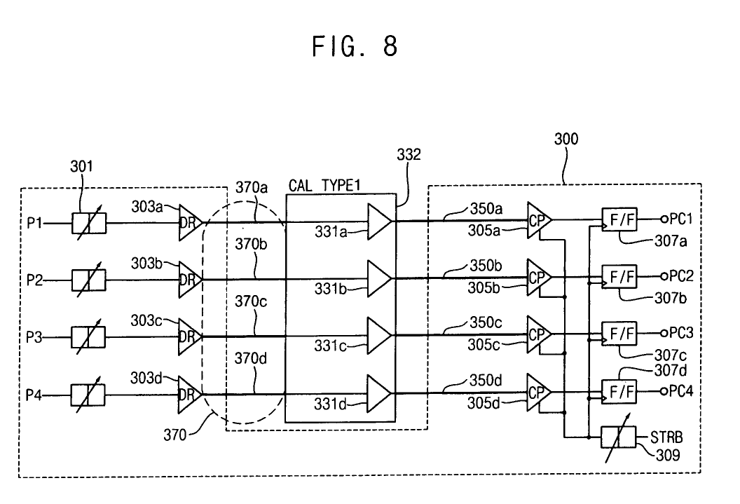

FIG. 8 illustrates another exemplary embodiment of a semiconductor testing apparatus having a first calibration board. Referring to FIG. 8, a plurality of drivers 303a, 303b, 303c and 303d may be respectively connected to fan-out buffers 331a, 331b, 331c and 331d in a first calibration board 332 through respective first delay paths 370a, 370b, 370c and 370d. Each fan-out buffers 331a, 331b, 331c and 331d may be respectively connected to a corresponding comparator 305a, 305b, 305c and 305d of the plurality of comparators 305 through respective third delay paths 350a, 350b, 350c and 350d.

According to an embodiment of the present invention, time skews of each clock signal, e.g., PC1, PC2, and so forth, due to respective delay paths 350 may be measured according to the method discussed previously with respect to FIGS. 2, i.e., evaluation of skew values by employing the first calibration board 332.

Further, the time skews of each clock signal due to each respective transmission path 370 may be measured and calibrated by subtracting a phase value of each signal outputted from a corresponding flip-flop 307 measured in FIG. 2 from a phase value of each signal outputted from a corresponding flip-flop 307 measured in FIG. 8. In this case, only one calibration board, i.e., the first calibration board 332, may be sufficient for proper calibration of the semiconductor testing apparatus according to an embodiment of the present invention. Alternatively, the time skews of each clock signal due to the transmission paths 370 may be measured and calibrated by subtracting skew values, as opposed to phase values, of respective flip-flop 307 output signals. Furthermore, the time skews of each clock signal due to the transmission paths 370 of the drivers 303 may be also obtained by subtracting a skew value of each clock signal corresponding to a respective delay path 350 measured in FIG. 2 from a skew value of each signal outputted from a corresponding flip-flop 307 measured in FIG. 8.

A variable delay circuit 301 may be controlled so that the skew values of the clock signals due to the respective drivers 303 may be calibrated to have specific desirable values.

Without intending to be bound by theory, it is believed that the present invention is advantageous because the inventive semiconductor testing apparatus may provide simultaneous measurement of time skews and calibration thereof in a plurality of testing channels, such the calibration time of the semiconductor testing apparatus having a plurality of drivers and a plurality of comparators corresponding to a plurality of channels may be reduced.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor testing apparatus, comprising;
N drivers, N being a natural number no less than two;
at least one transmission path coupled to at least one of the N drivers;
at least one calibration board coupled to the at least one transmission path;
N comparators; and
N delay paths, each delay path of the N delay paths has a skew value and is coupled between the calibration board one of the N comparators.

2. The semiconductor testing apparatus as claimed in claim 1, wherein the skew value of each of the N delay paths is unique.

3. The semiconductor testing apparatus as claimed in claim 1, wherein the at least one transmission path has a first transmission predetermined delay value.

4. The semiconductor testing apparatus as claimed in claim 1, further comprising N transmission paths, each transmission path of the N transmission paths having a skew value.

5. The semiconductor testing apparatus as claimed in claim 1, wherein the at least one calibration board includes N fan-out buffers, each fan-out buffer of the N fan-out buffers having a first calibration predetermined delay value.

6. The semiconductor testing apparatus as claimed in claim 5, further comprising a second calibration board having N transmission channels, each transmission channel of the N transmission channels having a second calibration predetermined delay value.

7. The semiconductor testing apparatus as claimed in claim 6, wherein the first calibration predetermined delay value is equal to the second calibration predetermined delay value.

8. The semiconductor testing apparatus as claimed in claim 6, wherein each transmission channel of the N transmission channels includes a printed circuit board.

9. The semiconductor testing apparatus as claimed in claim 6, wherein each transmission channel of the N transmission channels includes a fan-out buffer.

10. The semiconductor testing apparatus as claimed in claim 1, wherein the calibration board has a number and a configuration of channels that are comparable to a number and a configuration of terminals of a device under test.

11. A method of calibrating a semiconductor testing apparatus having N drivers and N comparators, N being a natural number no less than two, the method comprising:
generating N first test clock signals by the N drivers;
transmitting the N first test clock signals to a first calibration board to generate N first response clock signals;
passing each response clock signal of the N first response clock signals through one of N delay paths into one of the N comparators to generate N first output signals;
comparing each output signal of the N first output signals to a reference value to obtain a first skew value for each delay path of the N delay paths;
generating N second test clock signals by the N drivers;
transmitting the N second test clock signals to a second calibration board to generate N second response clock signals;
passing each response clock signal of the N second response clock signals through one of the N delay paths into one of the N comparators to generate N second output signals; and
subtracting from each output signal of the N second output signals the first skew value of a corresponding output signal of the N first output signals to determine N second skew values.

12. The method as claimed in claim 11, wherein comparing each output signal of the N first output signals to a reference value includes measuring phase differences between a first output signal of the N first output signals and each of the N first output signals.

13. The method as claimed in claim 12, wherein comparing each output signal of the N first output signals to a reference value further comprises adjusting the N first skew values to have desirable values.

14. The method as claimed in claim 11, wherein transmitting the N second test clock signals to a second calibration board includes passing the N second test clock signals through N transmission paths having transmission delay values.

15. The method as claimed in claim 14, wherein determining the N second skew values includes calculating corresponding transmission delay values.

16. The method as claimed in claim 15, wherein calculating the transmission delay includes adjusting the transmission delay values to have desirable values.

17. The method as claimed in claim 11, further comprising calibrating each output signal of the N second output signals to have desirable values.
